(19) United States
(12) Patent Application Publication
(10) Pub. No.: US 2004/0126967 A1
(43) Pub. Date: Jul. 1, 2004

(54) Method of manufacturing non-volatile memory device

(76) Inventor: Kwang Chul Joo, Kyungki-Do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/636,050

(22) Filed: Aug. 7, 2003

(30) Foreign Application Priority Data
Dec. 26, 2002 (KR) 2002-84313

(51) Int. Cl. H01L 21/336; H01L 21/31; H01L 21/469

(52) U.S. Cl. 438/257; 438/775

(57) ABSTRACT

Disclosed is a method of manufacturing the non-volatile memory device. The method comprises the step of forming a floating gate on a semiconductor substrate, implementing nitrification treatment for the top surface of the floating gate, forming a silicon nitride film on the floating gate experienced by the nitrification treatment, forming a metallic oxide film on the silicon nitride film, implementing annealing in order to supplement oxygen for the metallic oxide film, and forming a control gate on the metallic oxide film. As the leakage current due to irregularity of the interface is prevented, electrical characteristics could be improved. Furthermore, the process equipment used in the existing DRAM (dynamic random access memory) capacitor could be utilized intact.

### BACKGROUND OF THE INVENTION

1. Field of the Invention

The present invention relates to a method of manufacturing semiconductor device, and more particularly, to a method of manufacturing non-volatile memory device capable of preventing reduction in the dielectric constant and capacitance of the entire dielectric film, by prohibiting oxidization of an underlying floating gate by oxygen diffusion even if a metallic oxide film is used as a dielectric film.

2. Background of the Related Art

As the degree of integration in the flash memory device is increased, the size of the cell, i.e., the design rule of the floating gate is reduced. Accordingly, in order to secure capacitance of the floating gate necessary for operation of the flash memory device, the ONO (oxide/nitride/oxide) film is used as the dielectric film. A metallic oxide film such as Ta₂O₅, etc. has recently been developed. The metallic oxide film such as Ta₂O₅, etc. that could be applied as the dielectric film of the flash memory device having the design rule of below 0.13 μm and 0.11 μm has a dielectric constant higher about 3˜4 times than the existing Si₃N₄ film (ε=7) or the SiO₂ film (ε=3.8). This metallic oxide film, however, has some problems that it is applied as the dielectric film.

A total capacitance in the metallic oxide film such as Ta₂O₅, etc. is significantly lowered since it forms a low dielectric layer through an interfacial reaction with a floating gate (doped polysilicon film) in a subsequent annealing process for securing the dielectric constant. In general, the subsequent annealing process of the metallic oxide film experiences low temperature annealing, such as oxygen plasma or ultraviolet (UV)-ozone (O₃), and high temperature annealing such as furnace annealing or a rapid thermal process (RTP). Although the dielectric characteristic of the metallic oxide film can be improved as annealing proceeds, the dielectric constant and capacitance of the entire dielectric film are reduced since the underlying silicon film is oxidized by oxygen diffusion.

### SUMMARY OF THE INVENTION

Accordingly, the present invention is contrived to substantially obviate one or more problems due to limitations and disadvantages of the related art.

An object of the present invention is to provide a method of manufacturing non-volatile memory device capable of preventing reduction in the dielectric constant and capacitance of the entire dielectric film, by prohibiting oxidization of an underlying floating gate by oxygen diffusion even if a metallic oxide film is used as a dielectric film.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of manufacturing non-volatile memory device according to the present invention is characterized in that it comprises the steps of forming a floating gate on a semiconductor substrate, implementing nitrification treatment for the top surface of the floating gate, forming a silicon nitride film on the floating gate experienced by the nitrification treatment, forming a metallic oxide film on the silicon nitride film, implementing annealing in order to supplement oxygen for the metallic oxide film, and forming a control gate on the metallic oxide film.

In another aspect of the present invention, it is to be understood that both the foregoing general description and the following detailed description of the present invention are exemplary and explanatory and are intended to provide further explanation of the invention as claimed.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1˜FIG. 5 are cross-sectional views of non-volatile memory device for explaining a method of manufacturing the device according to a preferred embodiment of the present invention.

### DETAILED DESCRIPTION OF THE PREFERRED EMBODIMENT

Reference will now be made in detail to the preferred embodiments of the present invention, examples of which are illustrated in the accompanying drawings, in which like reference numerals are used to identify the same or similar parts. If it is described in the following description that one layer exists on the other layer, this means that one layer may exist immediately on the other layer and a third layer may be intervened between the two layers. Furthermore, the thickness and dimension of each of layers in the drawings are exaggerated for convenience of explanation and clarity.

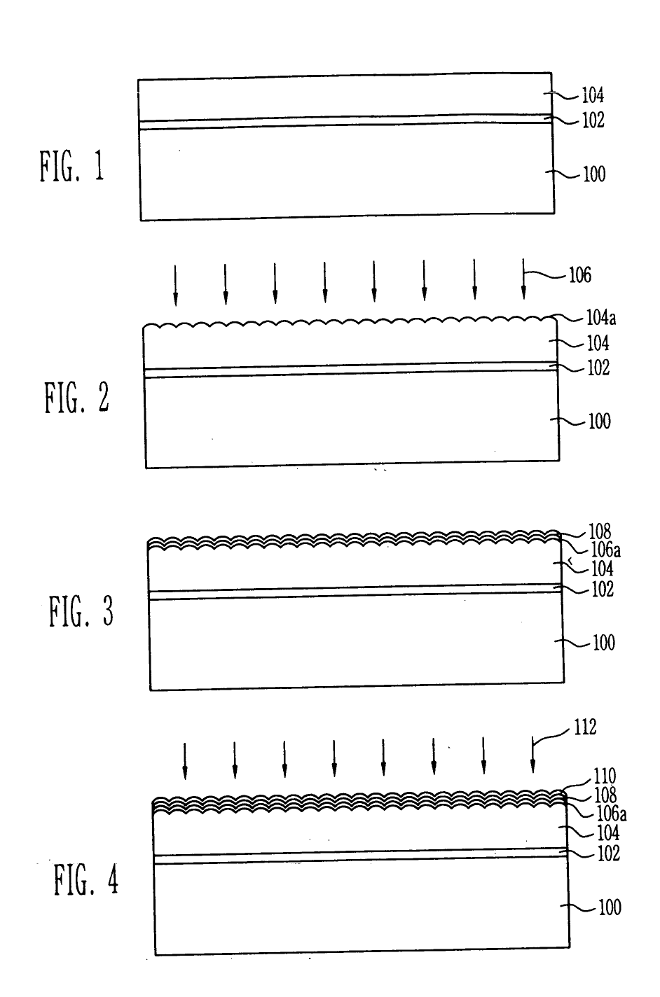

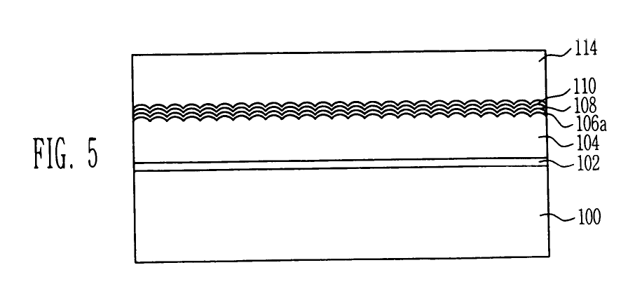

FIG. 1˜FIG. 5 are cross-sectional views of non-volatile memory device for explaining a method of manufacturing the device according to a preferred embodiment of the present invention.

Referring to FIG. 1, a gate oxide film 102 is formed on a semiconductor substrate 100. It is preferred that the gate oxide film 102 is formed using a wet oxidization mode. For example, the gate oxide film 102 may be formed by implementing wet oxidization at a temperature of about 750° C.˜800° C. and implementing annealing under a nitrogen (N₂) atmosphere at a temperature of about 900° C.˜910° C. for 20˜30 minutes.

In order to form a floating gate 104 being a charge storage node on the gate oxide film 102, a polysilicon film on which a dopant is doped is deposited. The polysilicon film may be formed using SiH₄ or Si₂H₆ gas and PH₃ gas by means of a LP-CVD (low pressure-chemical vapor deposition) method. At this time, the doped dopant may be phosphorous (P), etc. It is preferred that the dopant is doped at the dose of about 1.0E20˜3.0E20 atoms/cc. Further, it is preferred that the polysilicon film 106 is formed in thickness of about 1000˜2000 Å at a temperature of 550˜620° C. and a low pressure of about 0.1˜3 Torr.

By reference to FIG. 2, in order to increase the surface area of the floating gate 104, a hemispherical grain (HSG) 104a is formed. Capacitance of the cell transistor is also increased by the hemispherical grain (HSG) 104a. The surface of the floating gate 104 is then experienced by nitrification treatment 106. The nitrification treatment 106 is implemented in the furnace using a NH₃ gas. It is preferred that the nitrification treatment 106 is implemented at a temperature of about 600˜850° C. and a pressure of 10˜100 torr for about 30˜120 minutes. A nitride film 106a is formed on the top surface of the floating gate 104 by means of the nitrification treatment 106.

With reference to FIG. 3, a native oxide film (not shown) is formed on the nitride film 106a. At this time, the native oxide film may be formed by exposing the semiconductor substrate 100 in the air.

Next, a silicon nitride (Si₃N₄) film 108 is deposited on the native oxide film. The silicon nitride film 108 may be deposited using a NH₃ gas and a SiH₂Cl₂ gas, or the NH₃ gas and a SiH₄. It is preferred that the silicon nitride film 108 is deposited at a temperature of about 600˜800° C. and a pressure of about 0.05˜0.5 torr by means of the low pressure-chemical vapor deposition method. The silicon nitride film 108 is formed in thickness of about 3˜50 Å.

Turning to FIG. 4, a metallic oxide film 110 is formed on the silicon nitride film 108. The metallic oxide film 110 may be a Ta₂O film, a TiO₂ film, a Ta₃N₄ film, a TaON film., or the like. The metallic oxide film 110 is formed using a metal precursor such as Ta(OC₂H₅)₅ as a source material and oxygen (O₂) as a reaction gas. The metallic oxide film 110 is formed in thickness of about 20˜150 Å.

Thereafter, in order to supplement the amount of oxygen depletion within the metallic oxide film 110, high temperature annealing 112 is implemented under an oxygen (O₂) atmosphere or a N₂O atmosphere The high temperature annealing 112 may be a rapid thermal process (RTP) or furnace annealing process. It is preferable that the high temperature annealing 112 is implemented at a temperature of about 700˜900° C. for 30˜120 minutes.

Referring to FIG. 5, a control gate 114 being a plate electrode is formed on the metallic oxide film 110. The control gate 114 may be formed to have a structure on which a titanium nitride (TiN) film, a polysilicon film or a titanium nitride film and a polysilicon film are sequentially stacked. The control gate 114 is formed in thickness of about 500˜2000 Å by means of the CVD (chemical vapor deposition) method.

As described above, according to the present invention, as oxidization of the floating gate being the charge storage node, i.e., the Si electrode is prevented, the interface between the metallic oxide film such as the Ta₂O₅ film and the Si electrode is changed to a layer in which Si₃N₄ (ε=7) component in SiO₂ (ε=3.8) is sufficient and capacitance is thus increased. Therefore, the present invention has new effects that it can prevent the leakage current due to irregularity of the interface and improve electrical characteristics. Furthermore, the present invention has am advantageous effect that it can utilize the process equipment used in the existing DRAM (dynamic random access memory) capacitor.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed are:

1. A method of manufacturing non-volatile memory device, comprising the steps of:
forming a floating gate on a semiconductor substrate;
implementing nitrification treatment for the top surface of the floating gate;
forming a silicon nitride film on the floating gate experienced by the nitrification treatment;
forming a metallic oxide film on the silicon nitride film;
implementing annealing in order to supplement oxygen for the metallic oxide film; and
forming a control gate on the metallic oxide film.

2. The method as claimed in claim 1, further comprising the step of forming a native oxide film on the floating gate experienced by the nitrification treatment before the step of forming the silicon nitride film after the step of implementing the nitrification treatment.

3. The method as claimed in claim 1, wherein the nitrification treatment is implemented using a NH₃ gas in the furnace.

4. The method as claimed in claim 3, wherein the nitrification treatment is implemented at a temperature of 600˜850° C. and a pressure of 10˜100 torr for 30˜120 minutes.

5. The method as claimed in claim 1, wherein the silicon nitride film is formed using a NH₃ gas and a SiH₂Cl₂ gas, or the NH₃ gas and a SiH₄ as a source gas by means of a low pressure-chemical vapor deposition (LP-CVD) method.

6. The method as claimed in claim 5, wherein the silicon nitride film is formed in thickness of about 3˜150 Å at a temperature of 600˜800° C. and a pressure of 0.05˜0.5 torr.

7. The method as claimed in claim 1, wherein the metallic oxide film is a Ta₂O₅ film, a TiO₂ film, a Ta₃N₄ film or a TaON film.

8. The method as claimed in claim 7, wherein the metallic oxide film is formed in thickness of about 20˜150 Å using a metal precursor as a source gas and oxygen (O₂) as a reaction gas.

9. The method as claimed in claim 1, wherein the annealing is implemented under an oxygen (O₂) atmosphere or a N₂O atmosphere at a temperature of about 700˜900° C. by means of a rapid thermal process(RTP) or furnace annealing.
